(19) United States
(12) Patent Application Publication
(10) Pub. No.: US 2022/0165773 A1
(43) Pub. Date: May 26, 2022

(54) LIGHT RECEIVING ELEMENT, LIGHT DETECTION DEVICE, AND LIGHT DETECTION METHOD

(71) Applicant: ABLIC Inc., Tokyo (JP)

(72) Inventor: Toshiro FUTATSUGI, Tokyo (JP)

(73) Assignee: ABLIC Inc., Tokyo (JP)

(21) Appl. No.: 17/517,657

(22) Filed: Nov. 2, 2021

(30) Foreign Application Priority Data
Nov. 26, 2020 (JP) 2020-195595

(51) Int. Cl. H01L 27/146; G02B 5/20; H01L 31/101

(52) U.S. Cl. CPC H01L 27/14623; H01L 31/1013; G02B 5/208; H01L 27/14665

(57) ABSTRACT

A light receiving element capable of detecting predetermined light among incident light beams with high sensitivity by a simple structure is provided. A light receiving element 100 that detects ultraviolet rays UV in sunlight SL includes an N-type semiconductor substrate 1, a P-type conductive layer 2 formed on the surface of the semiconductor substrate 1, an N-type ultraviolet absorption layer 3 formed on the surface of the conductive layer 2, transmitting visible rays VL in the sunlight SL, and absorbing the ultraviolet rays UV to excite electrons, and an N-type detection layer 4 formed at a position separated from the ultraviolet absorption layer 3 on the surface of the conductive layer 2 and detecting electrons flowing from the ultraviolet absorption layer 3 as a first photocurrent I_{L1}.

### CROSS-REFERENCE TO RELATED APPLICATIONS

This application claims the priority benefit of Japanese Patent Application No. 2020-195595, filed on Nov. 26, 2020. The entirety of the above-mentioned patent application is hereby incorporated by reference herein and made a part of this specification.

### BACKGROUND

### Technical Field

The present invention relates to a light receiving element, a light detection device, and a light detection method.

### Description of Related Art

In recent years, attention has been paid to the influence of ultraviolet radiation included in sunlight on human bodies and the environment, and ultraviolet information using an ultraviolet index, which is an index of the amount of ultraviolet rays, has been provided.

In order to detect the intensity of ultraviolet rays with high sensitivity by a light receiving element, it is necessary to reduce the influence of visible rays that become noise because sunlight includes visible rays that are stronger than ultraviolet rays.

Consequently, in order to reduce the influence of visible rays that become noise, an ultraviolet sensor that is connected so as to obtain a difference between an output of a light receiving element having high ultraviolet sensitivity and an output of a light receiving element having low ultraviolet sensitivity and cancels out a photocurrent due to visible rays to extract a photocurrent due to ultraviolet rays has been proposed (see, for example, Japanese Patent Laid-Open No. 2007-67331).

However, the ultraviolet sensor disclosed in Japanese Patent Laid-Open No. 2007-67331 has a problem that it is difficult to manufacture the ultraviolet sensor because it has to be made by adjusting not only the shape thereof but also the extent of injection, diffusion, and the like of impurities so that a photocurrent due to visible rays which is larger than a photocurrent due to ultraviolet rays can be generated and canceled out in substantially the same way in two types of light receiving element of which the structures are differentiated to have different ultraviolet sensitivities. That is, the light receiving elements disclosed in Japanese Patent Laid-Open No. 2007-67331 may have a reduced detection sensitivity for ultraviolet rays when a photocurrent due to visible rays which is larger than a photocurrent due to ultraviolet rays cannot be cancelled out.

### SUMMARY

An aspect of the present invention provides a light receiving element that can detect predetermined light among incident light beams with high sensitivity by a simple structure.

A light receiving element in an embodiment of the present invention is a light receiving element that detects light having a wavelength shorter than a predetermined wavelength among incident light beams, the light receiving element including a first conductive type semiconductor substrate, a second conductive type conductive layer formed on a surface of the semiconductor substrate, a first conductive type light absorption layer formed on a surface of the conductive layer, transmitting light having a wavelength equal to or greater than the predetermined wavelength among the incident light beams, and absorbing light having a wavelength shorter than the predetermined wavelength to excite electron-hole pairs, and a first conductive type detection layer formed at a position separated from the light absorption layer on the surface of the conductive layer, and detecting electrons or holes of the electron-hole pairs flowing from the light absorption layer as a first photocurrent.

According to an aspect of the present invention, it is possible to provide a light receiving element that can detect predetermined light among incident light beams with high sensitivity by a simple structure.

### BRIEF DESCRIPTION OF THE DRAWINGS

FIG. 1 is a schematic cross-sectional view illustrating a light receiving element in a first embodiment.

FIG. 2 is an enlarged view illustrating the surroundings of an ultraviolet absorption layer in FIG. 1.

FIG. 3 is an energy band diagram along a line I-I in FIG. 2.

FIG. 4A is an energy band diagram when UVA, UVB, and UVC are detected in the first embodiment.

FIG. 4B is an energy band diagram when UVB and UVC are detected in the first embodiment.

FIG. 4C is an energy band diagram when UVC is detected in the first embodiment.

FIG. 5 is a block diagram illustrating an example of a light detection device using the light receiving element in the first embodiment.

FIG. 6 is a diagram illustrating a method of obtaining a spectroscopic spectrum in the first embodiment.

FIG. 7 is a schematic cross-sectional view illustrating a light receiving element in a second embodiment.

FIG. 8 is an enlarged view illustrating the surroundings of an ultraviolet absorption layer in FIG. 7.

FIG. 9A is an energy band diagram when UVA, UVB, and UVC are detected in the second embodiment.

FIG. 9B is an energy band diagram when UVB and UVC are detected in the second embodiment.

FIG. 9C is an energy band diagram when UVC is detected in the second embodiment.

### DESCRIPTION OF THE EMBODIMENTS

Hereinafter, embodiments of the present invention will be described in detail with reference to the drawings.

Meanwhile, the drawings are schematic, and a relationship between film thicknesses and plane dimensions, ratios between respective film thicknesses, and the like may not be as shown in the drawings. Further, in a semiconductor substrate, a surface on a side where another film or layer is laminated using a semiconductor manufacturing process is referred to as an “upper surface”, and a surface on a side facing the upper surface is referred to as a “lower surface”. Further, in the following description, the quantities, positions, shapes, structures, sizes, and the like of a plurality of films and semiconductor elements obtained by structurally combining these films are not limited to the embodiments shown below, and the quantities, positions, shapes, structures, sizes, and the like which are preferable for implementing the present invention are arbitrary.

In addition, hereinafter, a first conductive type is assumed to be an N-type, and a second conductive type is assumed to be a P-type.

### First Embodiment

In a first embodiment, description will be given of a light receiving element that detects ultraviolet rays included in sunlight when irradiated with sunlight as incident light. For this reason, a “predetermined wavelength” is set to 400 nm which is a boundary between visible rays and ultraviolet rays.

Light Receiving Element

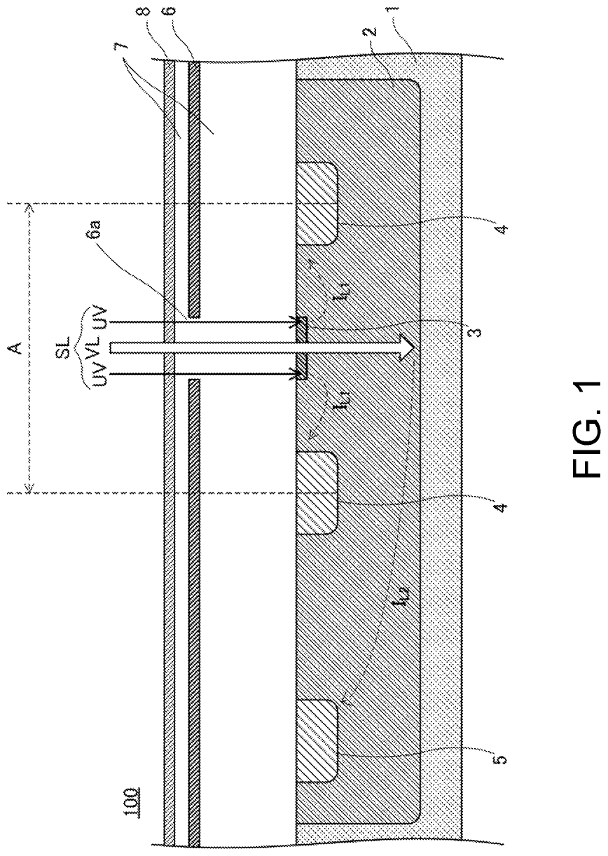

FIG. 1 is a schematic cross-sectional view illustrating the light receiving element in the first embodiment.

As shown in FIG. 1, a light receiving element 100 in the first embodiment includes a semiconductor substrate 1, a conductive layer 2, an ultraviolet absorption layer 3 as a light absorption layer, a detection layer 4, a recovery layer 5, a metal light shielding film 6, an insulating interlayer 7, and a protection film 8. The light receiving element 100 is formed in a region surrounded by an element isolation structure such as a shallow trench isolation (STI) of the surface of the semiconductor substrate 1.

The detection layer 4 and the recovery layer 5 are provided to be able to apply a voltage and to detect a current. A voltage of the conductive layer 2 is given by the recovery layer 5. In addition, although not shown in the drawings, the semiconductor substrate 1 and the ultraviolet absorption layer 3 are also provided with terminals such that different voltages are able to be applied thereto separately.

When sunlight SL is incident from above, the light receiving element 100 detects electrons that have reached the detection layer 4 which is adjacent to the ultraviolet absorption layer 3 so as to be spaced apart therefrom in the surface of the conductive layer 2, among electrons excited in the ultraviolet absorption layer 3 by ultraviolet rays UV included in the sunlight SL, as a first photocurrent IL. That is, the light receiving element 100 is maintained at a fixed distance from a junction portion in which a photocurrent is generated by visible radiation by disposing the detection layer 4 on the surface of the conductive layer 2, and the intensity of ultraviolet radiation is able to be indicated by the first photocurrent I_{L1} detected by separating off an unnecessary photocurrent by a potential barrier of the conductive layer 2 between the ultraviolet absorption layer 3 and the detection layer 4.

In this manner, the light receiving element 100 can detect predetermined light among incident light beams with high sensitivity by a simple structure. In addition, regarding the light receiving element 100, since it is not necessary to form two types of light receiving element as in the ultraviolet sensor disclosed in Japanese Patent Laid-Open No. 2007-67331, it is possible to reduce the size of a layout area and to form light receiving elements on the same substrate as that of an integrated circuit on which signal processing is performed.

Further, in the light receiving element 100, visible rays VL having passed through the ultraviolet absorption layer 3 are recovered by the recovery layer 5 as a second photocurrent I_{L2} generated in a junction portion between the semiconductor substrate 1 and the conductive layer 2. Thereby, the light receiving element 100 can separate the first photocurrent I_{L1} caused by the ultraviolet rays UV and the second photocurrent I_{L2} caused by the visible rays VL, and thus the ultraviolet rays UV can be selectively detected with high sensitivity.

Hereinafter, details of the light receiving element 100 will be described.

The semiconductor substrate 1 is an N-type silicon semiconductor substrate.

The conductive layer 2 is a P-type diffusion layer into which P-type impurities are injected, and is formed on the surface of the semiconductor substrate 1.

The thickness (diffusion depth) of the conductive layer 2 is preferably equal to or greater than 200 nm and equal to or less than 500 nm, in that in this case as many electrons excited due to the emission of the visible rays VL by the conductive layer 2 flow into a semiconductor substrate as possible and do not flow into the detection layer 4, that is, in that the influence of visible rays is reduced.

The ultraviolet absorption layer 3 is an N-type diffusion layer into which N-type impurities are injected and is formed on the surface of the conductive layer 2. The ultraviolet absorption layer 3 generates electron-hole pairs by transmitting the visible rays VL in the sunlight SL and absorbing the ultraviolet rays UV. The number of electron-hole pairs generated in the ultraviolet absorption layer 3 increases as the ultraviolet rays UV becomes stronger.

Meanwhile, when irradiated with the ultraviolet rays UV, there is a concern that an interface state may be formed between the ultraviolet absorption layer 3 and the insulating interlayer film 7, or a fixed charge may be generated in the insulating interlayer film 7. Thus, in order to improve reliability, it is preferable to set an outermost surface to be of a high concentration N+ type regarding the impurity concentration of the ultraviolet absorption layer 3.

The diffusion depth of impurities in the ultraviolet absorption layer 3, that is, the thickness of the ultraviolet absorption layer 3 is preferably equal to or greater than 10 nm and equal to or less than 100 nm, and more preferably equal to or greater than 10 nm and equal to or less than 50 nm in that in this case the ultraviolet rays UV are easily absorbed and the visible rays VL are easily transmitted.

Regarding the ease of electrons, excited by the ultraviolet absorption layer 3, reaching the detection layer 4 through the conductive layer 2, electrons excited at the vicinity of the center of the ultraviolet absorption layer 3 are less likely to reach the detection layer 4, and electrons excited at either of the two ends of the ultraviolet absorption layer 3 are more likely to reach the detection layer 4 from the viewpoint of the energy required for the electrons to move to the detection layer 4. In this respect, regarding the width of the ultraviolet absorption layer 3, that is, the length of the ultraviolet absorption layer 3 in FIG. 1 in an in-plane direction, a larger length does not contribute to detection sensitivity, and a smaller length is preferable in that in this case the size of the layout area can be reduced. A length of less than or equal to 0.5 μm is preferable.

Regarding the length of the ultraviolet absorption layer 3, that is, the length of the ultraviolet absorption layer 3 in FIG. 1 in a depth direction, a larger length is preferable in that sensitivity is improved by an increase in the size of an area irradiated with sunlight SL.

In addition, it is possible to increase an area irradiated with sunlight SL by repeating a region indicated by A in FIG. 1 to arrange a plurality of ultraviolet absorption layers 3 and detection layers 4.

The detection layer 4 is an N+ type diffusion layer into which N-type impurities are injected at high concentration, and is formed at a position separated from the ultraviolet absorption layer 3 on the surface of the conductive layer 2. That is, the detection layer 4 is formed on the surface of the conductive layer 2, and thus the detection layer 4 is disposed at a position where it is difficult to detect a second photocurrent I_{L2} generated at a junction portion between the semiconductor substrate 1 and the conductive layer 2 due to visible rays passing through the ultraviolet absorption layer 3. In addition, the detection layer 4 is adjacent to the ultraviolet absorption layer 3 so as to be spaced apart therefrom on the surface of the conductive layer 2. Thereby, the detection layer 4 detects electrons flowing from the ultraviolet absorption layer 3 as a first photocurrent I_{L1} by excluding an unnecessary photocurrent by a potential barrier of the conductive layer 2 between the ultraviolet absorption layer 3 and the detection layer 4.

Meanwhile, it is possible to adjust the height of the potential barrier of the conductive layer 2 with respect to the ultraviolet absorption layer 3 by changing a voltage of at least any one of the ultraviolet absorption layer 3, the detection layer 4, and the recovery layer 5. This will be described below.

It is preferable that a gap between the ultraviolet absorption layer 3 and the detection layer 4 be small in that in this case it is possible to improve the sensitivity because electrons excited by the ultraviolet absorption layer 3 easily reach the detection layer 4, and to reduce a layout area.

The recovery layer 5 is a P+ type diffusion layer and is formed on the surface of the conductive layer 2. The recovery layer 5 recovers a second photocurrent I_{L2}, which is generated at a junction portion between the semiconductor substrate 1 and the conductive layer 2 due to the conductive layer 2 due to visible rays passing through the ultraviolet absorption layer 3.

Meanwhile, the second photocurrent I_{L2} caused by recovered visible rays may be used in other circuits and the like.

The metal light shielding film 6 is formed on the entire surface above the semiconductor substrate 1, shields sunlight SL, and includes an opening portion 6a above the ultraviolet absorption layer 3. The sunlight SL is incident on the ultraviolet absorption layer 3 from the opening portion 6a. It is possible to prevent an unnecessary photocurrent from flowing into the detection layer 4 due to the absorption of visible rays in a region other than the ultraviolet absorption layer 3 due to the metal light shielding film 6 including the opening portion 6a.

A material of the metal light shielding film 6 is aluminum in the present embodiment, but is not particularly limited as long as it is a metal having a light blocking effect. Examples of the material include copper, tungsten, alloys thereof, and the like.

The insulating interlayer 7 is a silicon oxide film to which phosphorus and boron are added (hereinafter referred to as a “boro-phospho silicate glass (BPSG) film”), and is formed over the entire region of the semiconductor substrate 1 so as to cover the metal light shielding film 6.

Meanwhile, in the present embodiment, the insulating interlayer 7 is configured as a BPSG film, but is not limited thereto. The insulating interlayer 7 may be configured to have, for example, a laminated structure of a none-doped silicate glass (NSG) film and a BPSG film, a laminated structure of a tetra-ethyl-ortho-silicate (TEOS) film and a BPSG film, or the like.

In addition, when irradiated with ultraviolet rays UV, there is a concern that an interface state may be formed between the ultraviolet absorption layer 3 and the insulating interlayer 7, or a fixed charge may be generated in the insulating interlayer 7. Thus, in order to improve reliability, it is preferable that, in a region having a thickness of approximately 10 nm in contact with the ultraviolet absorption layer 3, the insulating interlayer 7 be configured as a thermal oxidation film of silicon or configured as a high temperature oxide (HTO) film.

The protection film 8 is a silicon nitride film and is formed in the entire region of the insulating interlayer 7. The degree of absorption of ultraviolet rays UV in the silicon nitride film strongly depends on film formation conditions. In a light detection device which is used to detect only UVA and UVB, a silicon nitride film absorbing UVC can be used, but in the case of a light detection device used to detect UVC, it is preferable that a silicon nitride film transmitting UVC up to a wavelength of approximately 250 nm be used. When there is no problem of reliability, it is also possible to remove a silicon nitride film only in a light receiving region.

Meanwhile, in the present embodiment, the protection film 8 is configured to have a single-layer structure of a silicon nitride film, but is not limited thereto. For example, the protection film 8 may be configured to have a two-layer structure of a silicon oxide film and a silicon nitride film.

Next, a flow channel of a first photocurrent I_{L1} that flows into the detection layer 4 from the ultraviolet absorption layer 3 in the light receiving element 100 of the present embodiment will be described using an energy band diagram.

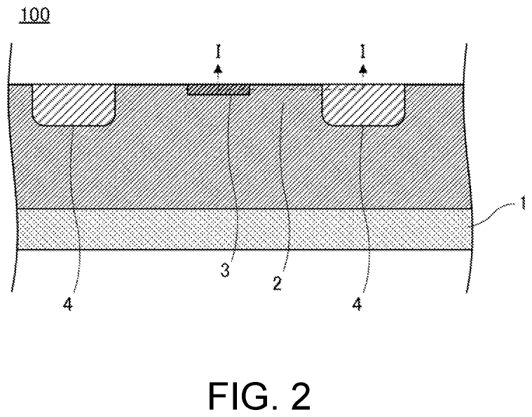

FIG. 2 is an enlarged view illustrating the surroundings of an ultraviolet absorption layer in FIG. 1, and illustrates a line I-I which is a cutting-plane line.

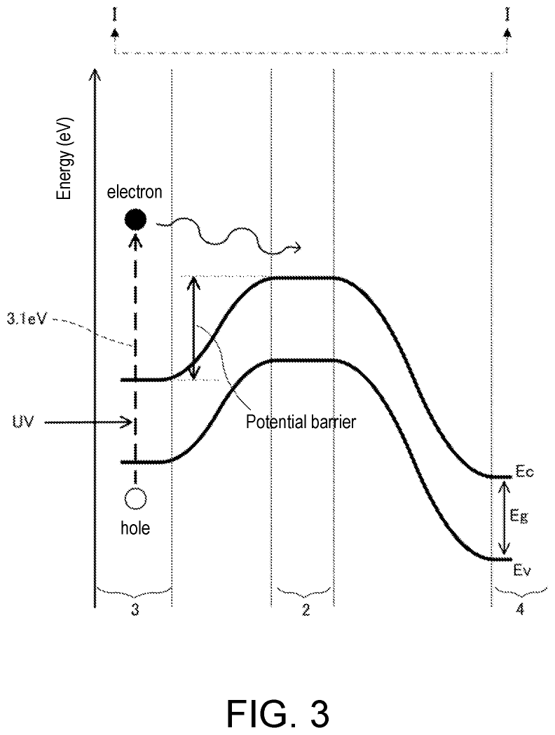

FIG. 3 is an energy band diagram along the line I-I in FIG. 2. In FIG. 3, a vertical axis represents an energy, and a horizontal axis represents a positional relationship between the conductive layer 2, the ultraviolet absorption layer 3, and the detection layer 4. In addition, an energy band structure shown in FIG. 3 illustrates a state where a voltage Vs (for example, 0.5 V) is applied to the ultraviolet absorption layer 3, 0 V is applied to the conductive layer 2 and the semiconductor substrate 1, and a voltage Vd (for example, 1.8 V) is applied to the detection layer 4. Ec indicates an energy level of a lower end of a conductor, Ev indicates an energy level of an upper end of a valence band, Eg indicates a bandgap energy of 1.1 eV in the present embodiment, and a relation of Eg=Ec−Ev is established.

As shown in FIG. 3, when ultraviolet rays UV having a wavelength of, for example, 400 nm are incident on the ultraviolet absorption layer 3, electron-hole pairs are generated from the ultraviolet absorption layer 3. At this time, the energy of electrons excited in a conduction band from a valence band of the ultraviolet absorption layer 3 is 3.1 eV, which is much larger than Eg. That is, many electrons in the generated electron-hole pairs acquire enough energy to get over a potential barrier in the conductive layer 2 between the ultraviolet absorption layer 3 and the detection layer 4. The light receiving element 100 detects electrons that have got over the potential barrier as a first photocurrent I_{L1} with the detection layer 4. A light detection device using the light receiving element 100 can calculate the intensity (mW/cm²) of ultraviolet rays UV by performing necessary processing such as storage and calculation using a circuit or the like connected to the light receiving element 100 from the first photocurrent I_{L1} detected by the light receiving element 100.

Here, the height of the potential barrier means the amount of energy that prevents electrons from getting over a certain region.

Method of Manufacturing Light Receiving Element

The light receiving element 100 can be easily manufactured by a general semiconductor manufacturing process using, for example, photolithography.

In this manner, the light receiving element 100 has a simple structure and can be formed on the same substrate as that of an integrated circuit on which signal processing is performed. Further, in the light receiving element 100, a first photocurrent I_{L1} caused by ultraviolet rays UV and a second photocurrent I_{L2} caused by visible rays VL can be separated from each other by the structure, and thus the ultraviolet rays UV can be selectively detected with high sensitivity.

Ultraviolet Lays Classification Function of Light Receiving Element

Ultraviolet rays are classified into ultraviolet A waves (UVA: wavelength of 400 nm to 315 nm), ultraviolet B waves (UVB: wavelength of 315 nm to 280 nm), and ultraviolet C waves (UVC: wavelength of 280 nm to 200 nm) depending on wavelengths from the viewpoint of the influence on a human body or an environment. UVA darkens the skin and causes aging, UVB may cause skin inflammation and cause skin cancer, and UVC is absorbed by the ozone layer and does not reach the surface of the Earth, but has a strong bactericidal action and is used in germicidal lamps. For this reason, it is useful to detect the ultraviolet rays according to this classification.

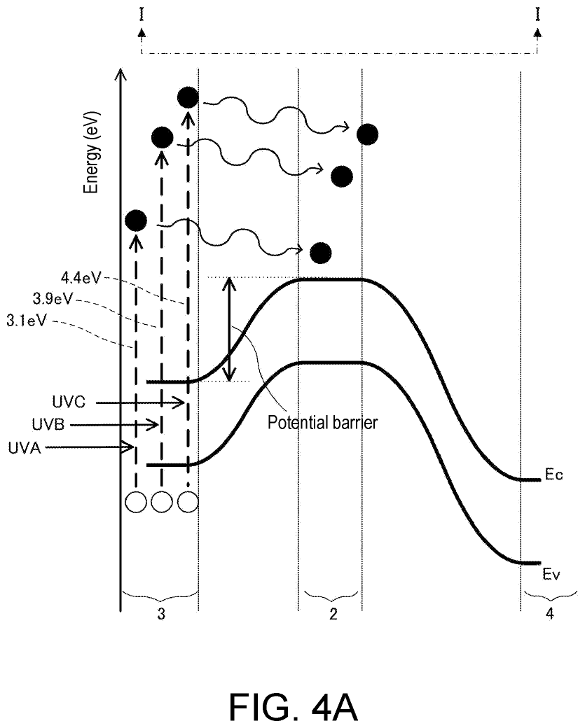

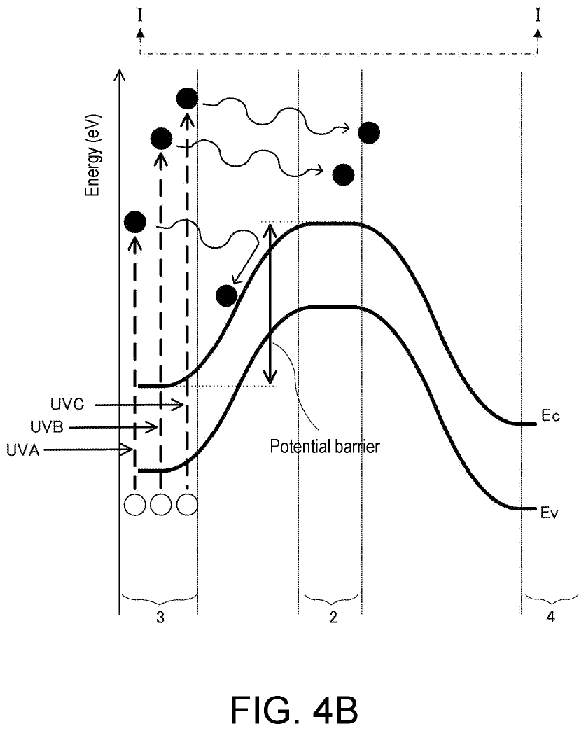

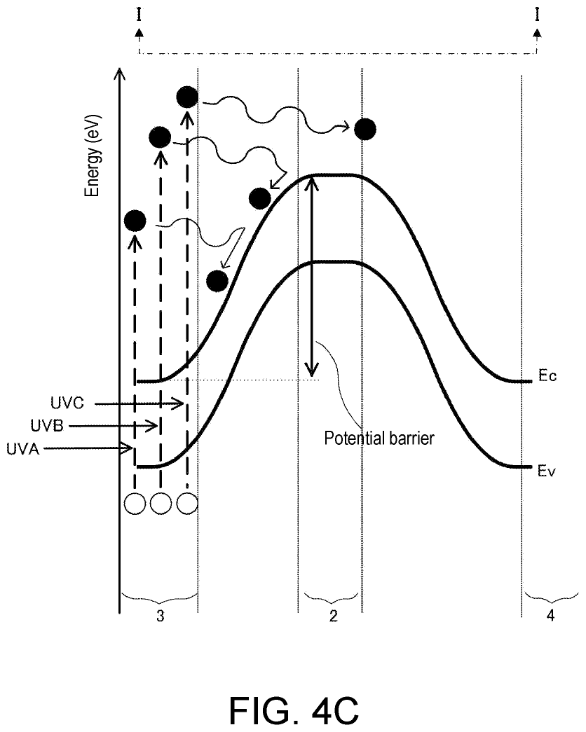

The light receiving element 100 can classify ultraviolet rays UV by changing voltages to be applied to the conductive layer 2, the ultraviolet absorption layer 3, and the detection layer 4. Focusing on the energy band structure along the line I-I in FIG. 2, voltages to be applied are changed, and thus it is possible to substantially shift a predetermined wavelength by adjusting the height of a potential barrier of the conductive layer 2 between the ultraviolet absorption layer 3 and the detection layer 4 and to classify ultraviolet rays UV into UVA, UVB, and UVC and detect them as shown in FIGS. 4A to 4C below.

FIG. 4A is an energy band diagram when UVA, UVB, and UVC are detected in the first embodiment, and illustrates a state where a voltage Vs1 (for example, 0.5 V) is applied to the ultraviolet absorption layer 3, 0 V is applied to the conductive layer 2 and the semiconductor substrate 1, and a voltage Vd1 (for example, 1.8 V) is applied to the detection layer 4.

In FIG. 4A, similar to FIG. 3, a vertical axis represents an energy, and a horizontal axis represents a positional relationship between the conductive layer 2, the ultraviolet absorption layer 3, and the detection layer 4. This is the same as in FIGS. 4B and 4C below.

As shown in FIG. 4A, the energy of excited electrons changes depending on the wavelength of ultraviolet rays UV. Specifically, the energies of electrons excited by irradiating the ultraviolet absorption layer 3 with UVA having a wavelength of 400 nm, UVB having a wavelength of 315 nm, and UVC having a wavelength of 280 nm are 3.1 eV, 3.9 eV, and 4.4 eV, respectively. In the case of FIG. 4A, the excited electrons can climb over the potential barrier in the conductive layer 2 and are detected by the detection layer 4 as a first photocurrent I_{L1}(A+B+C).

FIG. 4B is an energy band diagram when UVB and UVC are detected in the first embodiment. An energy band structure shown in FIG. 4B illustrates a state where a voltage Vs2 (for example, 1.3 V) is applied to the ultraviolet absorption layer 3, 0 V is applied to the conductive layer 2 and the semiconductor substrate 1, and a voltage Vd2 (for example, 1.8 V) is applied to the detection layer 4. Since the voltage Vs2 higher than the voltage Vs1 is applied to the ultraviolet absorption layer 3, a potential barrier in the conductive layer 2 becomes higher.

As shown in FIG. 4B, electrons excited by UVA cannot climb over the potential barrier. On the other hand, electrons excited by UVB or UVC can climb over the potential barrier and are detected by the detection layer 4 as a first photocurrent I_{L1}(B+C).

FIG. 4C is an energy band diagram when UVC is detected in the first embodiment. An energy band structure shown in FIG. 4C illustrates a state where a voltage Vs3 (for example, 1.8 V) is applied to the ultraviolet absorption layer 3, 0 V is applied to the conductive layer 2 and the semiconductor substrate 1, and a voltage Vd3 (for example, 1.8 V) is applied to the detection layer 4. Since the voltage Vs3 higher than the voltage Vs2 is applied to the ultraviolet absorption layer 3, a potential barrier becomes higher than that in FIG. 4B.

As shown in FIG. 4C, electrons excited by UVA or UVB cannot climb over the potential barrier. On the other hand, electrons excited by UVC can climb over the potential barrier and are detected by the detection layer 4 as a first photocurrent I_{L1}(C).

In other words, the light receiving element 100 can change the height of the potential barrier in the conductive layer 2 between the detection layer 4 and the ultraviolet absorption layer 3 by a voltage to be applied to at least any one of the semiconductor substrate 1, the conductive layer 2, the ultraviolet absorption layer 3, and the detection layer 4 and detect electrons of electron-hole pairs excited by an energy exceeding that of the height of the potential barrier due to ultraviolet rays UV as a first photocurrent.

In this manner, ultraviolet rays UV can be detected and classified as UVA, UVB, and UVC by calculating the first photocurrent I_{L1} detected by changing a voltage applied to the ultraviolet absorption layer 3 in a stepwise manner stored in a circuit or the like connected to the light receiving element 100.

Specifically, in a case where a first photocurrent I_{L1}(A) is due to UVA is obtained, the first photocurrent can be calculated by the following Expression 1.

$${I}_{L 1} ( A ) = {I}_{L 1} ( A + B + C ) - {I}_{L 1} ( B + C ) \qquad ( 1 )$$

In a case where a first photocurrent I_{L1}(B) due to UVB is obtained, the first photocurrent can be calculated by the following Expression 2.

$${I}_{L 1} = {I}_{L 1} ( B + C ) - {I}_{L 1} ( C ) \qquad ( 2 )$$

Further, in a case where a first photocurrent I_{L1}(C) due to UVC is obtained, a first photocurrent I_{L1}(D) due to a deep ultraviolet rays (represented by D below) having a wavelength of 200 nm is detected by increasing the potential barrier shown in FIG. 4C, and can be calculated by the following Expression 3.

$${I}_{L 1} ( C ) = {I}_{L 1} ( C + D ) - {I}_{L 1} ( D ) \qquad ( 3 )$$

Meanwhile, in the above description, a first photocurrent has been detected for each of wavelengths, that is, a wavelength of 400 nm (UVA), a wavelength of 315 nm (UVB), and a wavelength of 280 nm (UVC). However, for example, it is possible to obtain information regarding a spectral spectrum of an ultraviolet region by finely dividing wavelengths at intervals of 10 nm to detect first photocurrents.

In addition, a first photocurrent may be amplified by impact ionization to increase sensitivity by applying a high positive voltage to the detection layer 4 and strengthening an electric field between the conductive layer 2 and the detection layer 4.

Light Detection Device

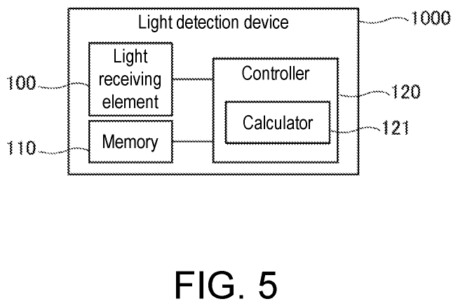

FIG. 5 is a block diagram illustrating a light detection device in the first embodiment.

As shown in FIG. 5, a light detection device 1000 includes a light receiving element 100, a memory 110, and a controller 120 that controls the memory 110.

The light receiving element 100 is the above-mentioned light receiving element 100.

Meanwhile, it is possible to improve sensitivity for detecting ultraviolet rays UV by disposing a plurality of the light receiving elements 100.

The memory 110 stores the value of a first photocurrent I_{L1} detected by the light receiving element 100 for each application voltage condition on the basis of an instruction of the controller 120. In addition, the memory 110 stores a program for executing a light detection method to be described later, and the like.

The memory 110 is constituted by, for example, a random access memory (RAM), a read only memory (ROM), or the like.

The controller 120 includes a calculator 121 that performs calculation using the value of the first photocurrent I_{L1} stored in the memory 110. The controller 120 performs control for storing the value of the first photocurrent I_{L1} detected by the light receiving element 100 in the memory 110 and causing the calculator 121 to perform calculation using the value of the first photocurrent I_{L1} stored in the memory 110. The control of calculation is performed by a program or the like stored in the memory 110.

The controller 120 is, for example, a central processing unit (CPU), a micro processing unit (MPU), or the like.

Light Detection Method

Next, a light detection method by which a spectral spectrum can be obtained using the light receiving element 100 by the light detection device 1000 will be described.

Regarding a method of causing the calculator 121 to perform calculation, in a case where ultraviolet rays UV are detected by being classified into UVA, UVB, and UVC, the calculation is performed as in the above-mentioned Expressions (1) to (3).

Meanwhile, a first photocurrent detected under a first bias condition is set to be I(1), and a first photocurrent detected under a second bias condition serving as a potential barrier higher than that in the first bias condition is set to be I(2) to obtain the following expression I(2)−I(1)=ΔI(1). This may be repeated sequentially to obtain the following expression I(n)−I(n−1)=ΔI(n−1) and obtain a spectral spectrum of sunlight from the obtained ΔI(1), ΔI(2), . . . , and ΔI(n−1). Here, n represents a natural number of 2 or greater.

Here, a bias condition is a condition in which a voltage Vs to be applied to the ultraviolet absorption layer 3 has been changed.

Alternatively, a spectral spectrum of sunlight may be obtained using the following light detection method.

In the light receiving element 100, the energy of electrons excited becomes higher as a wavelength of light absorbed by the ultraviolet absorption layer 3 becomes shorter as shown in FIG. 4A, and thus a photocurrent becomes larger as a wavelength of light absorbed by the ultraviolet absorption layer 3 becomes shorter. From this, it is possible to obtain a difference between first photocurrents detected under a plurality of bias conditions so as to divide an energy range and to detect the intensity of light in each wavelength range.

Meanwhile, in the present embodiment, a voltage Vs to be applied to the ultraviolet absorption layer 3 has been changed by a plurality of bias conditions. However, the present invention is not limited thereto, and at least one of voltages to be applied to the semiconductor substrate 1, the conductive layer 2, the ultraviolet absorption layer 3, and the detection layer 4 may be changed.

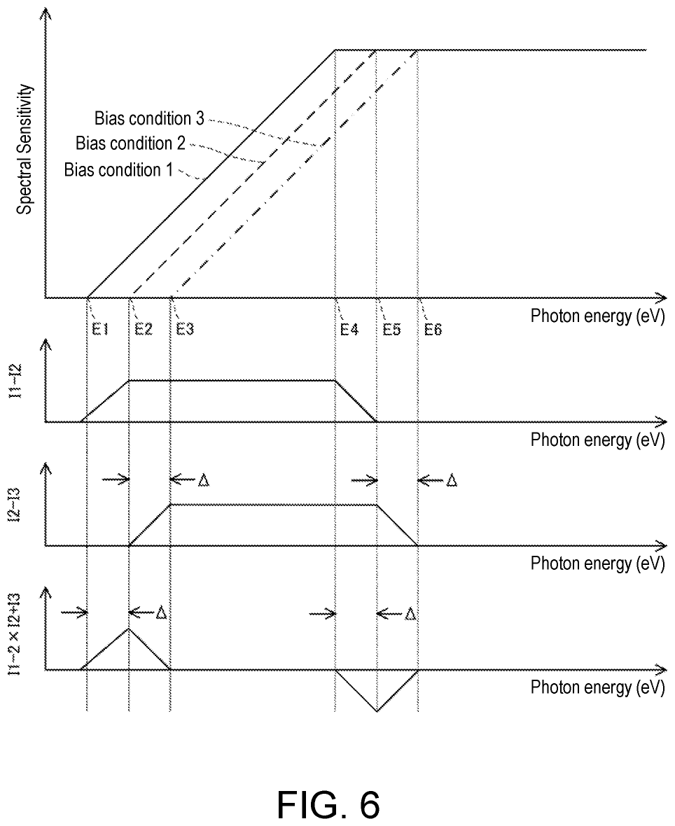

FIG. 6 is a diagram illustrating a method of obtaining a spectral spectrum in the first embodiment.

As shown in a graph at the uppermost stage in FIG. 6, bias conditions 1 to 3 are provided as a plurality of bias conditions.

In the bias condition 1, the sensitivity of the light receiving element 100 is 0 when an energy is less than E1, increases at a constant rate with respect to the energy when the energy is equal to or greater than E1 and equal to or less than E4, and saturates when the energy is equal to or greater than E4.

In the bias condition 2, the sensitivity of the light receiving element 100 is 0 when an energy is less than E2, increases at a constant rate with respect to the energy when the energy is equal to or greater than E2 and equal to or less than E5, and saturates when the energy is equal to or greater than E5.

In the bias condition 3, the sensitivity of the light receiving element 100 is 0 when an energy is less than E3, increases at a constant rate with respect to the energy when the energy is equal to or greater than E3 and equal to or less than E6, and saturates when the energy is equal to or greater than E6.

Here, in order to facilitate the understanding, intervals of E1, E2, and E3 and intervals of E4, E5, and E6 are set to be the same intervals, and the intervals are assumed to be Δ.

In addition, photocurrents detected under the bias conditions 1, 2, and 3 are assumed to be I1, I2, and I3.

Then, it is possible to obtain a photocurrent in an energy range of E1 to E5 from a difference between the photocurrent I1 and the photocurrent I2.

In addition, it is possible to obtain a photocurrent in an energy range of E2 to E6 from a difference between the photocurrent I2 and the photocurrent I3.

Further, it is possible to obtain a photocurrent in an energy range of E1 to E3 and a photocurrent in an energy range of E4 to E6 from the following expression of (I1−I2)−(I2−I3)=I1−2×I2+I3.

Here, when a filter is provided to prevent the incidence of light having a higher energy than E4, a photocurrent in an energy range of E1 to E3 can be obtained from I1−2×I2+I3.

In addition, since sunlight does not include UVC, the intensity of light in an energy range of E4 to E6 is 0 when the energy E4 is set not to be included in a region of UVC, and thus it is possible to obtain a photocurrent in an energy range of E1 to E3 from I1−2×I2+I3. The intensity of light can be obtained on the basis of the obtained photocurrent.

In this manner, in an example of the light detection method in the present invention, it is possible to obtain a spectral spectrum of sunlight by calculating first photocurrents detected under a plurality of bias conditions in which the value of a voltage to be applied to at least any one of the semiconductor substrate 1, the conductive layer 2, the ultraviolet absorption layer 3, and the detection layer 4 is changed in the light receiving element 100.

Meanwhile, in the present embodiment, an example in which light in a narrow energy range is detected under three bias conditions has been described, but the present invention is not limited thereto. It is also possible to obtain a spectral spectrum of light by detecting photocurrents under a larger number of bias conditions and performing data processing using an appropriate algorithm according to spectral sensitivity characteristics of the light receiving element.

### Second Embodiment

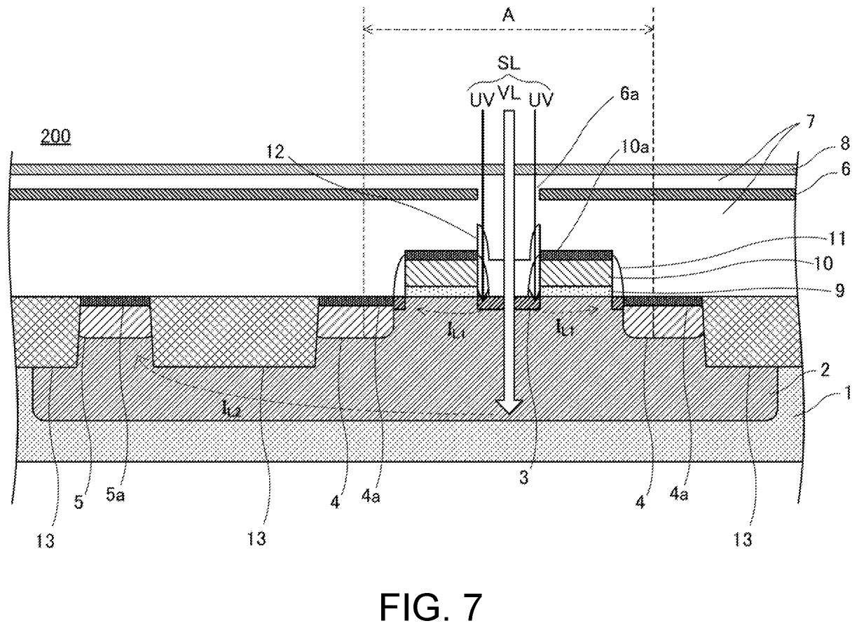

FIG. 7 is a schematic cross-sectional view illustrating a light receiving element in a second embodiment.

As shown in FIG. 7, a light receiving element 200 in the second embodiment further includes an insulating film 9 formed on a conductive layer 2 between an ultraviolet absorption layer 3 and a detection layer 4, an electrode 10 formed on the insulating film 9, a sidewall 11, and a silicide block 12 formed on the ultraviolet absorption layer 3, in addition to the configuration of the light receiving element 100 in the first embodiment.

The light receiving element 200 is formed in a region surrounded by an element isolation structure 13 such as an STI of the surface of the semiconductor substrate 1. In addition, the element isolation structure 13 is also provided between the detection layer 4 and the recovery layer 5. Silicides 10a, 4a, and 5a are formed on the surfaces of the electrode 10, the detection layer 4, and the recovery layer 5. Since an upper portion of the ultraviolet absorption layer 3 is covered with the silicide block 12, a silicide is not formed in the ultraviolet absorption layer 3.

N-type impurities for forming a shallow bond are injected into the ultraviolet absorption layer 3 and the detection layer 4. High-concentration N-type impurities are also injected into the detection layer 4 after the sidewall 11 is formed, and thus a shallow bond is formed only immediately below the sidewall 11 in the detection layer 4.

Meanwhile, impurities may be injected below the insulating film 9 to adjust the height of a potential barrier between the ultraviolet absorption layer 3 and the detection layer 4.

In addition, it is possible to increase an area irradiated with sunlight SL by repeating a region indicated by A in FIG. 7 to arrange a plurality of structures each ranging from the ultraviolet absorption layer 3 to the detection layer 4.

In the light receiving element 200 in the second embodiment, it is possible to change the height of a potential barrier of the conductive layer 2 between the ultraviolet absorption layer 3 and the detection layer 4 by a voltage Vg applied to the electrode 10 in addition to voltages to be applied to the conductive layer 2, the ultraviolet absorption layer 3, and the detection layer 4. For this reason, the light receiving element 200 is more advantageous than the light receiving element 100 in that a range in which an energy band structure can be adjusted is expanded, and it becomes easy to finely adjust the height of a potential barrier.

The insulating film 9 is a thermal oxidation silicon film, and is formed on the surface of the conductive layer 2 between the ultraviolet absorption layer 3 and the detection layer 4.

The electrode 10 is polysilicon into which N-type impurities are injected at high concentration, and is formed on the surface of the insulating film 9. In addition, it is possible to not only reduce resistance to a metal wiring and but also shield light up to the immediate vicinity of the ultraviolet absorption layer 3 by the silicide 10a formed on the surface of the electrode 10.

The sidewall 11 is a silicon oxide film and is formed on each of both side surfaces of the electrode 10.

The silicide block 12 is a silicon oxide film and is formed above the ultraviolet absorption layer 3 so that the ultraviolet absorption layer 3 is made into silicide in a manufacturing process and has no light blocking effect.

Next, a flow channel of a first photocurrent I_{L1} flowing into the detection layer 4 from the ultraviolet absorption layer 3 in the light receiving element 200 of the present embodiment will be described using an energy band diagram.

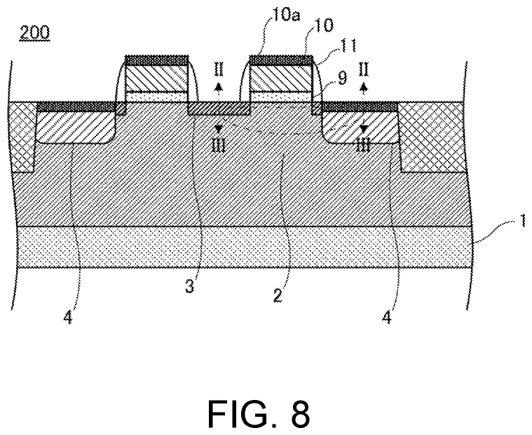

FIG. 8 is an enlarged view illustrating the surroundings of the ultraviolet absorption layer in FIG. 7 and illustrates a line II-II and a line III-III which are cutting-plane lines.

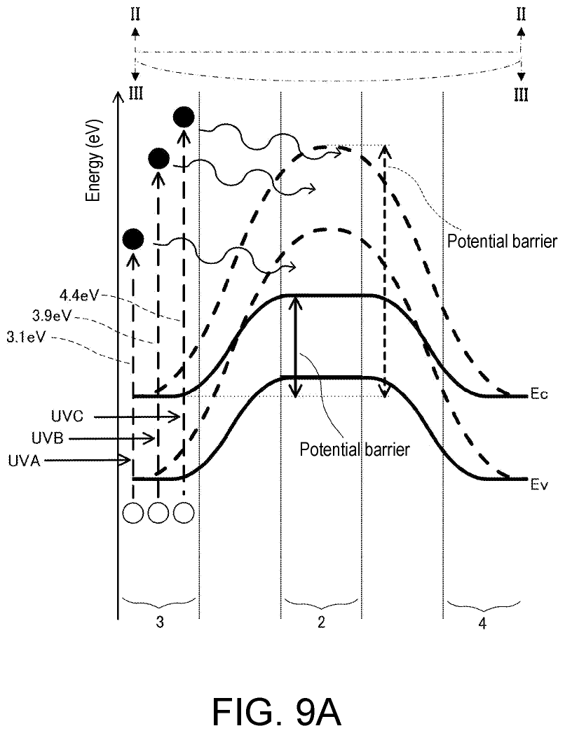

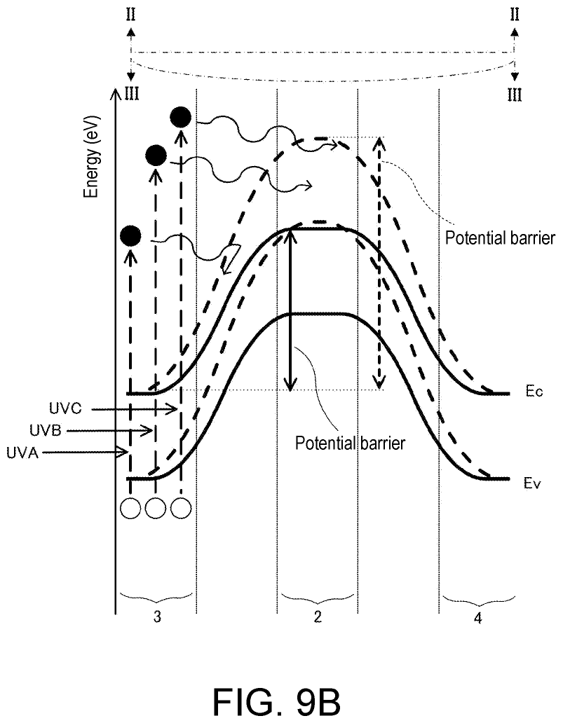

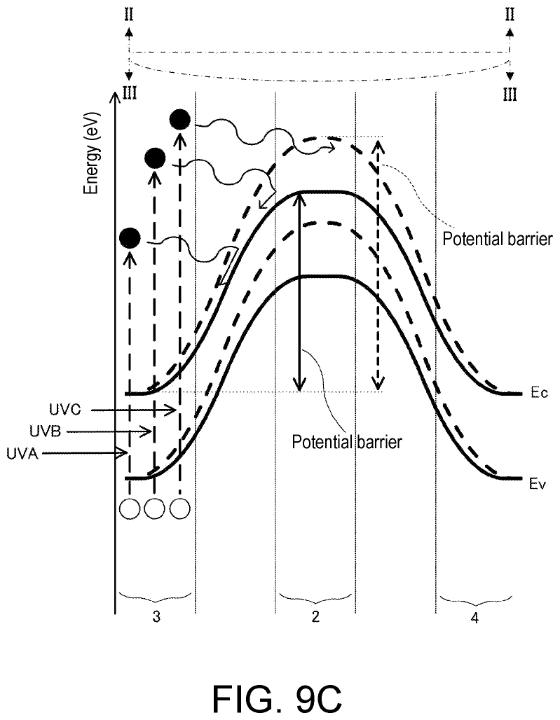

FIG. 9A is an energy band diagram when UVA, UVB, and UVC are detected in the second embodiment. FIG. 9A is an energy band structure along the line II-II and the line III-III in FIG. 7 and illustrates a state where a surface potential of the conductive layer 2 is made lower than that on the substrate side by 1.8 V by applying a voltage Vs4 (for example, 2.5 V) to the ultraviolet absorption layer 3, applying 0 V to the conductive layer 2, applying a voltage Vd4 (for example, 2.5 V) to the detection layer 4, and applying a voltage Vg21 to the electrode 10.

In FIG. 9A, similar to FIG. 4A, a vertical axis represents an energy, and a horizontal axis represents a positional relationship between the conductive layer 2, the ultraviolet absorption layer 3, and the detection layer 4. In addition, a solid line indicates an energy band structure along the line II-II shown in FIG. 7, and a dashed line indicates an energy band structure along the line III-III shown in FIG. 8.

As shown in FIG. 9A, in the energy band structure along the line II-II, similar to FIG. 4A, the energies of electrons excited by irradiating the ultraviolet absorption layer 3 with UVA having a wavelength of 400 nm, UVB having a wavelength of 315 nm, and UVC having a wavelength of 280 nm are 3.1 eV, 3.9 eV, and 4.4 eV, respectively. In this case, the excited electrons can climb over a potential barrier between the ultraviolet absorption layer 3 and the detection layer 4, and are detected by the detection layer 4 as a first photocurrent I_{L1}(A+B+C).

On the other hand, in the energy band structure along the line III-III, electrons excited by UVA, UVB, or UVC cannot climb over a potential barrier because the potential barrier is high. For this reason, the first photocurrent I_{L1}(A+B+C) is difficult to flow on the line III-III.

FIG. 9B is an energy band diagram when UVB and UVC are detected in the second embodiment, and illustrates a state where a surface potential of the conductive layer 2 is made lower than that on the substrate side by 1.3 V by applying Vg22 to the electrode 10.

In FIG. 9B, in the energy band structure along the line II-II, a potential barrier in the conductive layer 2 becomes higher than that in FIG. 8A. That is, similar to FIG. 4B, electrons excited by UVA cannot climb over the potential barrier. Electrons excited by UVB or UVC can climb over the potential barrier, and are detected by the detection layer 4 as a first photocurrent I_{L1}(B+C).

On the other hand, the energy band structure along the line III-III does not change greatly, and thus electrons excited by UVA, UVB, or UVC cannot climb over the potential barrier because the potential barrier is high, similar to FIG. 9A.

FIG. 9C is an energy band diagram when UVC is detected in the second embodiment.

FIG. 9C illustrates a state where a surface potential of the conductive layer 2 is made lower than that on the substrate side by 0.5 V by applying a voltage Vg23 to the electrode 10. In the energy band structure along the line II-II, a potential barrier becomes higher than that in FIG. 9B.

As shown in FIG. 9C, in the energy band structure along the line II-II, similar to FIG. 4C, electrons excited by UVA or UVB cannot climb over the potential barrier. Electrons excited by UVC can climb over the potential barrier and are detected by the detection layer 4 as a first photocurrent I_{L1}(C).

On the other hand, the energy band structure along the line III-III does not change greatly, and thus electrons excited by UVA, UVB, or UVC cannot climb over the potential barrier because the potential barrier is high, similar to FIG. 9A.

As shown in FIGS. 9A to 9C, similar to the light receiving element 100, in the light receiving element 200, it is possible to make it easier to separate a first photocurrent I_{L1} and a second photocurrent I_{L2} from each other than in the light receiving element 100, in addition to being able to classify ultraviolet rays UV into UVA, UVB and UVC and detect them. For this reason, the light receiving element 200 can selectively detect ultraviolet rays UV with higher sensitivity than the light receiving element 100.

The light receiving element 200 can be easily manufactured by a general semiconductor manufacturing process using, for example, photolithography, similar to the light receiving element 100.

Specifically, as a method of forming the ultraviolet absorption layer 3, impurities are injected before the silicide block 12 is formed. In addition, regarding the injection of impurities into the ultraviolet absorption layer 3, it is preferable to perform through injection through thermal oxidation silicon in order to reduce an interface level of a silicon/oxide film of the ultraviolet absorption layer 3 and cover an upper surface of the ultraviolet absorption layer 3 with a high-quality oxide film.

Further, in another example of the light detection method in the present invention, it is possible to obtain a spectral spectrum of sunlight by calculating first photocurrents detected under a plurality of bias conditions in which the value of a voltage to be applied to at least any one of the semiconductor substrate 1, the conductive layer 2, the ultraviolet absorption layer 3, the detection layer 4, and the electrode 10 is changed in the light receiving element 200.

As described above, the light receiving element according to each of the embodiments in the present invention is a light receiving element that detects light having a wavelength shorter than a predetermined wavelength among incident light beams, and includes a first conductive type semiconductor substrate, a second conductive type conductive layer formed on a surface of the semiconductor substrate, a first conductive type light absorption layer formed on a surface of the conductive layer, transmitting light having a wavelength equal to or greater than the predetermined wavelength among the incident light beams, and absorbing light having a wavelength shorter than the predetermined wavelength to excite electron-hole pairs, and a first conductive type detection layer formed at a position separated from the light absorption layer on the surface of the conductive layer, and detecting electrons or holes of the electron-hole pairs flowing from the light absorption layer as a first photocurrent.

Thereby, the light receiving element can detect predetermined light among incident light beams with high sensitivity by a simple structure.

Meanwhile, in the embodiments, a first conductive type is assumed to be an N-type, and a second conductive type is assumed to be a P-type. However, the first conductive type may be assumed to be a P-type, and the second conductive type may be assumed to be an N-type.

In addition, as another method of reducing the influence of visible rays in a light detection method, another light receiving element in which an ultraviolet absorption layer is set to be an N+ type and sensitivity for ultraviolet rays is intentionally lowered may be prepared to detect a first photocurrent flowing into a detection layer by absorbing visible rays and prepare correction data in advance, and the value of the correction data may be subtracted from a first photocurrent detected by the light receiving elements of each of the embodiments to remove the influence of visible rays.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A light receiving element that detects light having a wavelength shorter than a predetermined wavelength among incident light beams, the light receiving element comprising:
a first conductive type semiconductor substrate;
a second conductive type conductive layer formed on a surface of the semiconductor substrate;
a first conductive type light absorption layer formed on a surface of the conductive layer, transmitting light having a wavelength equal to or greater than the predetermined wavelength among the incident light beams, and absorbing light having a wavelength shorter than the predetermined wavelength to excite electron-hole pairs; and
a first conductive type detection layer formed at a position separated from the light absorption layer on the surface of the conductive layer, and detecting electrons or holes of the electron-hole pairs flowing from the light absorption layer as a first photocurrent.

2. The light receiving element according to claim 1, further comprising:
a second conductive type recovery layer formed on the surface of the conductive layer, and recovering a second photocurrent generated at a junction portion between the semiconductor substrate and the conductive layer by light having a wavelength equal to or greater than the predetermined wavelength passing through the light absorption layer.

3. The light receiving element according to claim 1, further comprising:
a metal light shielding film formed on an entire surface above the semiconductor substrate, shielding the incident light, and including an opening portion above the light absorption layer.

4. The light receiving element according to claim 2, further comprising:
a metal light shielding film formed on an entire surface above the semiconductor substrate, shielding the incident light, and including an opening portion above the light absorption layer.

5. The light receiving element according to claim 1,
wherein a height of a potential barrier in the conductive layer between the detection layer and the light absorption layer is changed by a voltage to be applied to at least any one of the semiconductor substrate, the conductive layer, the light absorption layer, and the detection layer, and electrons or holes of the electron-hole pairs excited by an energy exceeding the height of the potential barrier are detected as the first photocurrent by light having a wavelength shorter than the predetermined wavelength.

6. The light receiving element according to claim 2,
wherein a height of a potential barrier in the conductive layer between the detection layer and the light absorption layer is changed by a voltage to be applied to at least any one of the semiconductor substrate, the conductive layer, the light absorption layer, and the detection layer, and electrons or holes of the electron-hole pairs excited by an energy exceeding the height of the potential barrier are detected as the first photocurrent by light having a wavelength shorter than the predetermined wavelength.

7. The light receiving element according to claim 3,
wherein a height of a potential barrier in the conductive layer between the detection layer and the light absorption layer is changed by a voltage to be applied to at least any one of the semiconductor substrate, the conductive layer, the light absorption layer, and the detection layer, and electrons or holes of the electron-hole pairs excited by an energy exceeding the height of the potential barrier are detected as the first photocurrent by light having a wavelength shorter than the predetermined wavelength.

8. The light receiving element according to claim 4,
wherein a height of a potential barrier in the conductive layer between the detection layer and the light absorption layer is changed by a voltage to be applied to at least any one of the semiconductor substrate, the conductive layer, the light absorption layer, and the detection layer, and electrons or holes of the electron-hole pairs excited by an energy exceeding the height of the potential barrier are detected as the first photocurrent by light having a wavelength shorter than the predetermined wavelength.

9. The light receiving element according to claim 1, further comprising:
an insulating film formed on the surface of the conductive layer between the light absorption layer and the detection layer; and
an electrode formed on a surface of the insulating film and adjusting a height of the potential barrier by a voltage to be applied.

10. The light receiving element according to claim 2, further comprising:
an insulating film formed on the surface of the conductive layer between the light absorption layer and the detection layer; and
an electrode formed on a surface of the insulating film and adjusting a height of the potential barrier by a voltage to be applied.

11. The light receiving element according to claim 3, further comprising:
an insulating film formed on the surface of the conductive layer between the light absorption layer and the detection layer; and
an electrode formed on a surface of the insulating film and adjusting a height of the potential barrier by a voltage to be applied.

12. The light receiving element according to claim 5, further comprising:
an insulating film formed on the surface of the conductive layer between the light absorption layer and the detection layer; and
an electrode formed on a surface of the insulating film and adjusting a height of the potential barrier by a voltage to be applied.

13. The light receiving element according to claim 9, wherein
a silicide is formed in an upper portion of the electrode

14. The light receiving element according to claim 13, wherein
a silicide block is formed above the light absorption layer.

15. The light receiving element according to claim 9,
wherein a height of a potential barrier in the conductive layer between the detection layer and the light absorption layer is changed by a voltage to be applied to at least any one of the semiconductor substrate, the conductive layer, the light absorption layer, the detection layer, and the electrode, and electrons or holes of the electron-hole pairs excited by energy exceeding the height of the potential barrier are detected as the first photocurrent due to light having a wavelength shorter than the predetermined wavelength.

16. A light detection device in which a plurality of the light receiving elements according to claim 1 are disposed.

17. A light detection method using the light receiving element according to claim 5, the light detection method comprising:
obtaining a spectral spectrum of the incident light by calculating the first photocurrents detected under a plurality of bias conditions in which a value of a voltage to be applied to at least any one of the semiconductor substrate, the conductive layer, the light absorption layer, and the detection layer is changed.

18. A light detection method using the light receiving element according to claim 9, the light detection method comprising:
obtaining a spectral spectrum of the incident light by calculating the first photocurrents detected under a plurality of bias conditions in which values of voltages to be applied to at least any one of the semiconductor substrate, the conductive layer, the light absorption layer, the detection layer, and the electrode are combined with each other.

19. The light detection method according to claim 17,
wherein the first photocurrent detected according to a first bias condition is set to be I(1), and the first photocurrent detected according to a second bias condition serving as the potential barrier higher than that in the first bias condition is set to be I(2) to obtain the following expression of I(2)−I(1)=ΔI(1),
this is sequentially repeated to obtain the following expression of I(n)−I(n−1)=ΔI(n−1),
and a spectroscopic spectrum of the incident light is obtained from the obtained ΔI(1), ΔI(2), . . . , ΔI(n−1),
wherein n denotes a natural number of 2 or greater.

20. The light detection method according to claim 18,
wherein the first photocurrent detected according to a first bias condition is set to be I(1), and the first photocurrent detected according to a second bias condition serving as the potential barrier higher than that in the first bias condition is set to be I(2) to obtain the following expression of I(2)−I(1)=ΔI(1),
this is sequentially repeated to obtain the following expression of I(n)−I(n−1)=ΔI(n−1),
and a spectroscopic spectrum of the incident light is obtained from the obtained ΔI(1), ΔI(2), . . . , ΔI(n−1),
wherein n denotes a natural number of 2 or greater.
